(19) United States
(12) Patent Application Publication
(10) Pub. No.: US 2021/0010153 A1
(43) Pub. Date: Jan. 14, 2021

(54) SEMICONDUCTOR CRYSTAL GROWTH APPARATUS

(71) Applicant: Zing Semiconductor Corporation, Shanghai (CN)

(72) Inventors: Weimin Shen, Shanghai (CN); Gang Wang, Shanghai (CN); Xianliang Deng, Shanghai (CN); Hanyi Huang, Shanghai (CN); Wee Teck Tan, Shanghai (CN)

(21) Appl. No.: 16/904,561

(22) Filed: Jun. 18, 2020

(30) Foreign Application Priority Data
Jun. 18, 2019 (CN) 201910527023.0

(51) Int. Cl. C30B 15/22; C30B 29/06; C30B 15/10

(52) U.S. Cl. CPC C30B 15/22; C30B 15/10; C30B 29/06

(57) ABSTRACT

The invention provides a semiconductor crystal growth device. It comprises: a furnace body; a crucible, arranged inside the furnace body to receive the silicon melt; a pulling device arranged on the top of the furnace body, and is used to pulling out the silicon crystal ingot from the silicon melt body; a deflector, being barrel-shaped and disposed above the silicon melt in the furnace in a vertical direction, and the pulling device pulls the silicon crystal ingot passing through the deflector in a vertical direction; and a magnetic field applying device for applying a horizontal magnetic field to the silicon melt in the crucible; wherein the silicon crystal is pulled by the pulling device during the ingot passing through the deflector, the distance between the bottom of the deflector and the silicon crystal ingot in the direction of the magnetic field is greater than that in the direction perpendicular to the magnetic field. According to the semiconductor crystal growth device of the present invention, the quality of semiconductor crystal growth is improved.

### CROSS-REFERENCE TO RELATED APPLICATIONS

This application claims priority to P.R.C. Patent Application No. 201910527023.0 titled “a semiconductor crystal growth apparatus” filed on Jun. 18, 2019, with the State Intellectual Property Office of the People's Republic of China (SIPO).

### TECHNICAL FIELD

The present invention relates to the field of semiconductor technology, and in particular, to a semiconductor crystal growth device.

### BACKGROUND

The Czochralski Process (CZ) method is an important method for preparing single crystal silicon for semiconductor and solar energy. The high-purity silicon material placed in the crucible is heated by a thermal field composed of a carbon material to melt it, and then the seed is melted by The crystal is immersed in the melt and undergoes a series of (introduction, shoulder, equal diameter, finishing, cooling) processes to obtain a single crystal rod.

In the growth of semiconductor single crystal silicon or solar single crystal silicon using the CZ method, the temperature distribution of the crystal and the melt directly affects the quality and growth rate of the crystal. During the growth of CZ crystals, due to the existence of thermal convection in the melt, the distribution of trace impurities is uneven and growth stripes are formed. Therefore, how to suppress the thermal convection and temperature fluctuation of the melt during the crystal pulling process has been a widespread concern.

The crystal growth technology under a magnetic field generator (called MCZ) applies a magnetic field to a silicon melt as a conductor, subjecting the melt to a Lorentz force opposite to its direction of movement, obstructing convection in the melt and increasing the viscosity of the melt reduces impurities such as oxygen, boron, and aluminum from the quartz crucible into the melt, and then into the crystal, so that the grown silicon crystal can have a controlled oxygen content from low to high range, reducing The impurity stripes are widely used in semiconductor crystal growth processes. A typical MCZ technology is so called horizontal magnetic field crystal growth (HMCZ) technology, which applies a horizontal magnetic field to a semiconductor melt, and is widely used for the growth of large-sized and demanding semiconductor crystals.

In the crystal growth technology under a horizontal magnetic field device (HMCZ), the crystal growth furnace, thermal field, crucible, and silicon crystals are as symmetrical as possible in the circumferential direction, and the crucible and crystal rotation make the temperature distribution in the circumferential direction tends to be uniform. However, the magnetic field lines of the magnetic field applied during the application of the magnetic field pass from one end of the silicon melt in the quartz crucible to the other end in parallel. The Lorentz force generated by the rotating silicon melt is different in all directions in the circumferential direction, so the silicon melt flow and temperature distribution are inconsistent in the circumferential direction.

As shown in FIG. 1A and FIG. 1B, schematic diagrams of a temperature distribution below an interface between a crystal grown crystal and a melt in a semiconductor crystal growth apparatus are shown. Among them, FIG. 1A shows a graph of measured test points distributed on the horizontal surface of the silicon melt in the crucible, where one point is tested at an angle of θ=45° at a distance of 25 mm below the melt liquid level and a distance of L=250 mm from the center. FIG. 1B is a curve of the temperature distribution obtained by simulation calculation and test along each point at an angle θ with the X axis in FIG. 1A, where the solid line represents the temperature distribution map obtained by simulation calculation, and the dot diagram indicates the measured test method adopted distribution of temperature obtained. In FIG. 1A, the arrow A shows that the direction of rotation of the crucible is counterclockwise, and the arrow B shows that the direction of the magnetic field crosses the diameter of the crucible along the Y-axis direction. It can be seen from FIG. 1B that during the growth of the semiconductor crystal, both the results of the simulation calculation and the measured test method have shown that the temperature fluctuated on the circumference below the interface of a semiconductor crystal and the silicon melt liquid level changes with the angle during the growth of the semiconductor crystal.

According to the Voronkov crystal growth theory, the thermal equilibrium equation of the interface of the crystal and the liquid surface is as follows,

PS*LQ=Kc*Gc−Km*Gm.

Among them, LQ is the potential of silicon melt to silicon crystal phase transition, Kc, Km represent the thermal conductivity of the crystal and the melt, respectively; Kc, Km, and LQ are the physical properties of the silicon material; PS represents the crystal crystallization speed along the on-pull elongation direction that is approximately the pulling speed of the crystal; Gc, Gm are the temperature gradient (dT/dZ) of the crystal and the melt at the interface, respectively. Because the temperature below the interface of the semiconductor crystal and the melt exhibits periodic fluctuations with the change of the circumferential angle during the growth of semiconductor crystals, that is, the Gc of the temperature gradient (dT/dZ) of the crystal and the melt as the interface, Gm fluctuates. Therefore, the crystallization speed PS of the crystal in the circumferential angle direction fluctuates periodically, which is not conducive to controlling the quality of crystal growth.

For the reasons above, it is necessary to propose a new semiconductor crystal growth device to solve the problems in the prior art.

### SUMMARY

A series of simplified forms of concepts are introduced in the Summary of the Invention section, which will be described in further detail in the Detailed Description section. The summary of the invention is not intended to limit the key features and essential technical features of the claimed invention, and is not intended to limit the scope of protection of the claimed embodiments.

An objective of the present invention is to provide a semiconductor crystal growth apparatus, the semiconductor crystal growth apparatus comprises:

a furnace body;

a crucible being arranged inside the furnace body to contain a silicon melt;

a pulling device being arranged on the top of the furnace body and used for pulling out a silicon ingot from the silicon melt;

a deflector being barrel-shaped and disposed above the silicon melt in the furnace body in a vertical direction,

wherein the pulling device pulls the silicon ingot through the deflector in a vertical direction; and

a magnetic field applying device for applying a horizontal magnetic field to the silicon melt in the crucible;

wherein a distance between the bottom of the deflector and the silicon ingot in the direction of the magnetic field is greater than a distance between the bottom of the deflector and the silicon ingot in a direction perpendicular to the magnetic field during the pulling of the silicon ingot through the deflector by the pulling device.

In accordance with some embodiments, the cross section of the bottom of the deflector is oval.

In accordance with some embodiments, an angle between the long axis of the oval and the magnetic field is in a range of 0-45°.

In accordance with some embodiments, the distance between the bottom of the deflector and the silicon ingot is 10-40 mm in the short axis direction of the oval.

In accordance with some embodiments, the maximum distance between the bottom of the deflector and the silicon ingot is 20-60 mm in the long axis direction of the oval.

In accordance with some embodiments, the deflector comprises a tuning device to tune the distance between the bottom of the deflector and the silicon ingot.

In accordance with some embodiments, the deflector comprises an inner cylinder, an outer cylinder, and a heat insulating material; wherein the bottom of the outer cylinder is extended below the bottom of the inner cylinder and is closed to the bottom of the inner cylinder to form a cavity between the inner cylinder and the outer cylinder, and the heat insulation material is disposed in the cavity;

wherein the tuning device comprises an inserting member, the inserting member comprises a protruding portion and an inserting portion, and the inserting portion is inserted between a portion of the bottom of the outer cylinder extended below the bottom of the inner cylinder and the bottom of the inner cylinder, and the protrusion portion is located inside an outer wall of the bottom of the inner cylinder.

In accordance with some embodiments, the tuning device comprises at least two sections arranged along the deflector in a direction perpendicular to the magnetic field.

In accordance with some embodiments, the protrusion portion is arranged as an oval ring.

According to the semiconductor crystal growth device of the present invention, by setting different distances between the bottom of the deflector and the silicon ingot along the circumferential direction of the silicon crystal ingot, that is, the distance between the bottom of the deflector and the silicon ingot in the direction of the magnetic field is greater than the distance between the bottom of the deflector and the silicon ingot in a direction perpendicular to the magnetic field, the temperature distribution of the silicon melt below the interface between the silicon ingot and the silicon melt is tuned, such that the problem of fluctuations in the temperature distribution of the silicon melt below the interface between the semiconductor crystal and the liquid level of the silicon melt resulted from the applied magnetic field can be tuned during the growth of the semiconductor crystal, and effectively improve the uniformity of the temperature distribution of the silicon melt, thereby improving the uniformity of the crystal growth rate and the quality of crystal pulling.

### BRIEF DESCRIPTION OF THE DRAWINGS

Exemplary embodiments will be more readily understood from the following detailed description when read in conjunction with the appended drawings, in which:

FIGS. 1A and 1B are schematic diagrams of the temperature distribution below the interface between a crystal and a melt in a semiconductor crystal growth device;

FIG. 2 is a schematic structural diagram of a semiconductor crystal growth device according to the present invention;

FIG. 3 is a schematic cross-sectional positional arrangement of a crucible, a deflector, and a silicon crystal ingot in a semiconductor crystal growth apparatus according to an embodiment of the present invention;

FIG. 4 is a schematic structural diagram of a deflector in a semiconductor growth apparatus according to an embodiment of the present invention.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

In the following description, while the invention will be described in conjunction with various embodiments, it will be understood that these various embodiments are not intended to limit the invention. On the contrary, the invention is intended to cover alternatives, modifications and equivalents, which may be comprised within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details or with equivalents thereof. In other instances, well known methods, procedures, components, and circuits have not been described in detail as not to unnecessarily obscure aspects of the invention.

To understand the invention thoroughly, the following descriptions will provide detail steps to explain a method for crystal growth control of a shouldering process according to the invention. It is apparent that the practice of the invention is not limited to the specific details familiar to those skilled in the semiconductor arts. The preferred embodiment is described as follows. However, the invention has further embodiments beyond the detailed description.

The terminology used herein is for the purpose of describing particular embodiments only and is not intended to be limiting of example embodiments. As used herein, the singular forms “a,” “an” and “the” are intended to comprise the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

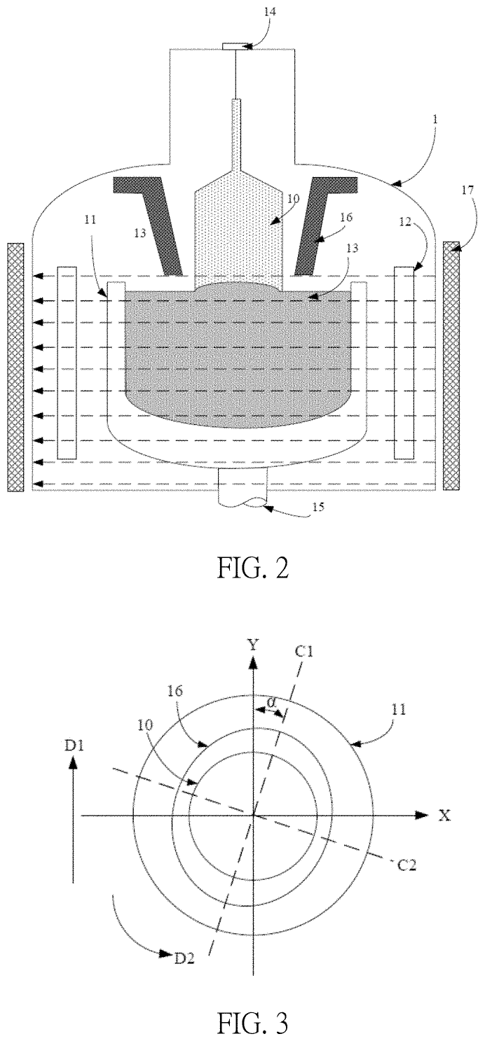

Referring to FIG. 2, a schematic structural diagram of a semiconductor crystal growth device according to one embodiment of the present invention is shown. The semiconductor crystal growth device includes a furnace body 1, a crucible 11 is disposed in the furnace body 1, and a heater 12 is provided on the outer side of the crucible 11 for heating. The crucible 11 contains a silicon melt 13. The crucible 11 is composed of a graphite crucible and a quartz crucible sheathed in the graphite crucible. The graphite crucible receives the heat provided by the heater to melt the polycrystalline silicon material in the quartz crucible to form a silicon melt. Each quartz crucible is used for a batch semiconductor growth process, and each graphite crucible is used for a multi-batch semiconductor growth process.

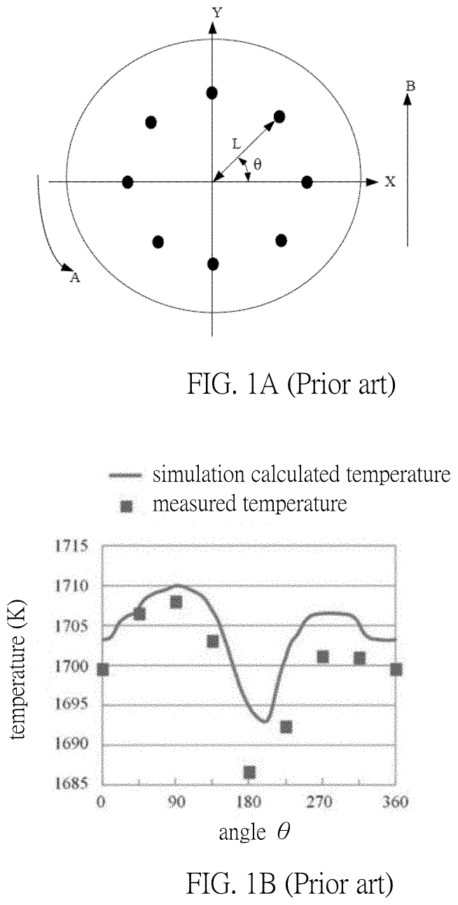

A pulling device 14 is provided on the top of the furnace body 1. Driven by the pulling device 14, a seed crystal may be pulled and pulled out of a silicon ingot 10 from the liquid level of the silicon melt, and a heat shield device is provided around the silicon ingot 10. The heat shield device, for example, as shown in FIG. 1, comprises a deflector 16, which is provided in a barrel type, serves as a heat shield device to isolate the quartz crucible during the crystal growth process and the thermal radiation generated by the silicon melt in the crucible on the surface of the crystal increases the cooling rate and axial temperature gradient of the ingot, and increases the number of crystal growth. On the other hand, it affects the thermal field distribution on the surface of the silicon melt and avoids the axial temperature gradient between the center and the edge is too large to ensure stable growth between the crystal ingot and the liquid level of the silicon melt. At the same time, the baffle is also used to guide the inert gas introduced from the upper part of the crystal growth furnace to make it a large flow rate passes through the surface of the silicon melt to achieve the effect of controlling the oxygen content and impurity content in the crystal. During the growth of the semiconductor crystal, driven by the pulling device 14, the silicon ingot 10 passes vertically through the deflector 16.

In order to achieve stable growth of the silicon ingot, a driving device 15 for driving the crucible 11 to rotate and move up and down is provided at the bottom of the furnace body 1. The driving device 15 drives the crucible 11 to keep rotating during the crystal pulling process in order to reduce silicon melting. The thermal asymmetry of the body causes the silicon crystal columns to grow equally.

In order to hinder the convection of the silicon melt, increase the viscosity in the silicon melt, reduce impurities such as oxygen, boron, and aluminum from the quartz crucible into the melt and then into the crystal, so that the grown silicon crystal can have the controlled low-to-high range oxygen content reduces impurity streaks. The semiconductor growth device further comprises a magnetic field applying device 17 located outside the furnace body 1 to apply a magnetic field to the silicon melt in the crucible.

Since the magnetic field lines of the magnetic field applied by the magnetic field applying device 17 pass from one end of the silicon melt in the crucible to the other end in parallel (see the dotted arrow in FIG. 2), the Lorentz force generated by the rotating silicon melt is on the circumference. The directions are different, so the flow and temperature distribution of the silicon melt are inconsistent in the circumferential direction, where the temperature along the direction of the magnetic field is higher than that in the direction perpendicular to the magnetic field. The inconsistency of the flow and temperature of the silicon melt manifests as the temperature of the melt below the interface of the semiconductor crystal and the melt fluctuates with the change of the angle, so that the crystallization speed PS of the crystal fluctuates, so that the semiconductor growth speed appears inconsistent on the circumference. Such non-uniformity is not suited for the quality control of semiconductor crystal growth.

For this reason, in the semiconductor growth device of the present invention, the deflector 16 is arranged along the circumferential direction of the silicon ingot, and the bottom of the deflector and the silicon ingot have different distances.

Along the circumference of the silicon ingot, a different distance is set between the bottom of the deflector and the silicon ingot, and the distance between the bottom of the deflector and the silicon ingot in the direction of the magnetic field is greater than that of perpendicular in the direction of the magnetic field. The distance between the bottom of the deflector and the silicon ingot in the direction of the magnetic field, where the distance is greater, the silicon melt liquid surface radiates more heat to the silicon ingot and the inside of the deflector. At a small distance, the heat from the silicon melt liquid surface radiates to the silicon ingot and the inside of the deflector, so that the temperature of the silicon melt liquid surface at a longer distance is lower than that of the silicon melt at a smaller distance. The temperature of the body fluid surface is much reduced, making up for the problem that the temperature in the direction of the magnetic field application is higher than the temperature perpendicular to the direction of the magnetic field application due to the effect of the applied magnetic field on the silicon melt flow. According to this, by setting the distance between the bottom of the deflector and the silicon crystal ingot, the temperature distribution of the silicon melt below the interface between the silicon ingot and the silicon melt can be tuned, so that the caused by the applied magnetic field can be tuned. The fluctuation of the temperature distribution of the silicon melt in the circumferential direction effectively improves the uniformity of the temperature distribution of the silicon melt, thereby improving the uniformity of the speed of crystal growth and the quality of crystal pulling.

Meanwhile, along the circumferential direction of the silicon ingot, there is a different distance between the bottom of the deflector and the silicon ingot, so that at a larger distance, the top of the furnace body communicates with the pressure and flow rate of the silicon melt liquid level flowing back through the deflector are reduced, and the shear force of the silicon melt liquid level is reduced. At a small distance, the top of the furnace body passes through the deflector, the pressure and flow rate at the position of the liquid level of the silicon melt increase, and the shear force of the liquid level of the silicon melt increases. Accordingly, by setting the distance between the bottom of the deflector and the silicon ingot, the flow of the silicon melt is increased. The structure is further tuned to make the flow state of the silicon melt more uniform along the circumferential direction, which further improves the uniformity of the crystal growth speed and the quality of the crystal pull. At the same time, by changing the flow state of the silicon melt, the uniformity of the oxygen content distribution in the crystal can be improved, and defects in crystal growth can be reduced.

According to an embodiment of the present invention, the cross section of the bottom of the deflector 16 is oval. Referring to FIG. 3, there is shown a schematic cross-sectional positional arrangement of crucibles, deflectors, and silicon ingots in a semiconductor crystal growth apparatus according to an embodiment of the present invention. As shown in FIG. 3, the bottom of the deflector 16 is oval, and its long axis is C1 and its short axis is C2. Arrow D1 is shown as the direction of the magnetic field, and arrow D2 is shown as the direction in which the crucible 11 is rotated. As can be seen from FIG. 3, since the long axis C1 is close to the Y axis, the distance from the bottom of the deflector 16 to the silicon ingot 10 in the direction of the magnetic field (Y axis direction) is greater than that in the direction perpendicular to the magnetic field (X axis direction).

Further, exemplarily, an angle a between the long axis of the oval and the magnetic field (Y-axis direction) ranges from 0 to 45°.

Further, in the short axis direction of the oval, the distance between the bottom of the deflector and the silicon ingot is 10-40 mm.

Further, in the long axis direction of the oval, the maximum distance between the bottom of the deflector and the silicon ingot is 20-60 mm.

Under the above setting form, the distance between the bottom of the deflector and the silicon ingot transitions from the minimum distance in the short axis direction to the maximum distance in the long axis direction, so that the liquid level of the silicon melt is radiated to the silicon ingot. The heat from the inside of the deflector is smoothly tuned with the distance between the bottom of the deflector and the silicon ingot, so that the temperature and flow structure of the silicon melt are smoothly tuned, and the temperature of the silicon melt and the flow structure caused by the drastic tune are avoided. Fluctuations, further improve the silicon melt temperature and flow structure uniformity, and improve the quality of crystal pulling. In an embodiment of the present invention, the angle a between the long axis of the oval and the magnetic field (Y-axis direction) is 45°, and in the direction of the short axis of the oval, the distance between the bottom of the deflector and the silicon ingot is 10 mm. In the direction of the long axis of the oval, the maximum distance between the bottom of the deflector and the silicon ingot is 60 mm.

According to an embodiment of the present invention, the deflector comprises a tuning device for tuning a distance between the bottom of the deflector and the silicon ingot. By adding a tuning device to change the distance between the bottom of the deflector and the silicon ingot, the manufacturing process of the deflector can be simplified on the existing deflector structure.

In one embodiment, the deflector includes an inner cylinder, an outer cylinder and a heat-insulation material, in which a bottom of the outer cylinder is extended below a bottom of the inner cylinder and is closed with the bottom of the inner cylinder to form a cavity between the inner cylinder and the outer cylinder, and the heat-insulation material is disposed in the cavity.

According to an embodiment of the present invention, the tuning device comprises an inserting member, the inserting member comprises a protruding portion and an inserting portion, and the inserting portion is inserted between a portion of the bottom of the outer cylinder extended below the bottom of the inner cylinder, and the bottom of the inner cylinder, and the protruding portion is located inside an outer wall of the bottom of the inner cylinder. Because the existing deflectors are generally set as cone barrels, the bottom of the deflectors is usually set in a circular cross section. By setting the deflector as an inserting member between the inner cylinder and the outer cylinder, the shape of the bottom of the deflector can be flexibly tuned by tuning the structure and shape of the inserting member without changing the structure of the existing deflector. The distance between the bottom of the deflector and the silicon ingot is tuned; thereby achieving the effect of the present invention by providing a tuning device having an inserting portion without changing the existing semiconductor growth device. At the same time, the inserting components can be manufactured and replaced in a modular manner, thereby adapting to various semiconductor crystal growth processes of different sizes, thereby saving costs.

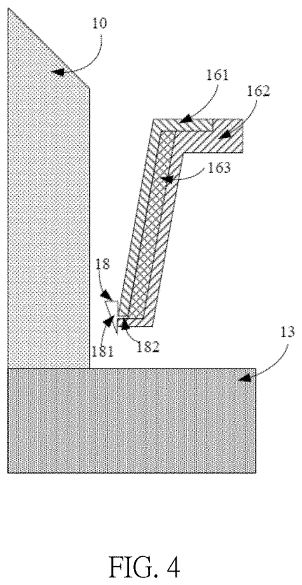

Referring to FIG. 4, there is shown a schematic structural diagram of a deflector in a semiconductor growth apparatus according to an embodiment of the present invention. Referring to FIG. 4, the deflector 16 includes an inner cylinder 161, an outer cylinder 162, and a heat insulating material 163 disposed between the inner cylinder 161 and the outer cylinder 162, wherein a bottom of the outer cylinder 162 extends below the bottom of the inner cylinder 161 and it is closed with the bottom of the inner cylinder 161 to form a cavity for containing the heat insulation material 163 between the inner cylinder 161 and the outer cylinder 162. Setting the deflector into a structure including an inner cylinder, an outer cylinder, and a heat insulating material can simplify the installation of the deflector. Exemplarily, the material of the inner cylinder and the outer cylinder is set to graphite, and the heat insulation material comprises glass fiber, asbestos, rock wool, silicate, aerogel felt, vacuum plate, and the like.

With continued reference to FIG. 4, a tuning device 18 is provided at the lower end of the deflector 16. The tuning device 18 comprises a protruding portion 181 and an inserting portion 182 which are provided to be inserted between the bottom of the outer cylinder 162 and a portion extended below the bottom of the inner cylinder 161 and the bottom of the inner cylinder 161. The tuning device is installed on the deflector in the form of an insert, without the need to modify the deflector, the installation of the tuning device can be realized, and the manufacturing and installation costs of the tuning device and the deflector are further simplified. At the same time, the position where the inserting part is inserted between the bottom of the outer cylinder and the bottom of the inner cylinder effectively reduces the heat conduction from the outer cylinder to the inner cylinder, reduces the temperature of the inner cylinder, and further reduces the radiant heat transfer from the inner cylinder to the ingot, effectively. The difference between the axial temperature gradient of the center and the periphery of the silicon ingot is reduced, and the quality of the crystal pulling is improved. Exemplarily, the tuning device is employed a material with low thermal conductivity, such as SiC ceramic, quartz, or the like.

Exemplarily, the tuning device may be provided in sections, such as two provided on the deflector along a direction perpendicular to the magnetic field; or may be provided along the circumference of the bottom of the deflector, such as set to oval ring.

It should be understood that the setting of the tuning device in sections or in an oval ring is merely exemplary, and any tuning device capable of tuning the distance between the bottom of the inner cylinder of the deflector and the silicon ingot is suitable for use in the present invention.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A semiconductor crystal growth apparatus, comprising:
a furnace body;
a crucible being arranged inside the furnace body to contain a silicon melt;
a pulling device being arranged on the top of the furnace body and used for pulling out a silicon ingot rod from the silicon melt;
a deflector being barrel-shaped and disposed above the silicon melt in the furnace body in a vertical direction,
wherein the pulling device pulls the silicon ingot through the deflector in a vertical direction; and
a magnetic field applying device for applying a horizontal magnetic field to the silicon melt in the crucible;
wherein a distance between the bottom of the deflector and the silicon ingot in the direction of the magnetic field is greater than a distance between the bottom of the deflector and the silicon ingot in a direction perpendicular to the magnetic field during the pulling of the silicon ingot through the deflector by the pulling device.

2. The apparatus according to claim 1, wherein the cross section of the bottom of the deflector is oval.

3. The apparatus according to claim 2, wherein an angle between the long axis of the oval and the magnetic field is in a range of 0-45°.

4. The apparatus according to claim 2, wherein the distance between the bottom of the deflector and the silicon ingot is 10-40 mm in the short axis direction of the oval.

5. The apparatus according to claim 3, wherein a maximum distance between the bottom of the deflector and the silicon ingot is 20-60 mm in the long axis direction of the oval.

6. The apparatus according to claim 1, wherein the deflector comprises a tuning device to tune the distance between the bottom of the deflector and the silicon ingot.

7. The apparatus according to claim 6, wherein the deflector comprises an inner cylinder, an outer cylinder, and a heat insulating material; wherein the bottom of the outer cylinder is extended below the bottom of the inner cylinder and is closed to the bottom of the inner cylinder to form a cavity between the inner cylinder and the outer cylinder, and the heat insulation material is disposed in the cavity;
wherein the tuning device comprises an inserting member, the inserting member comprises a protruding portion and an inserting portion, and the inserting portion is inserted between a portion of the bottom of the outer cylinder extended below the bottom of the inner cylinder and the bottom of the inner cylinder, and the protrusion portion is located inside an outer wall of the bottom of the inner cylinder.

8. The apparatus according to claim 6, wherein the tuning device comprises at least two sections arranged along the deflector in a direction perpendicular to the magnetic field.

9. The apparatus according to claim 7, wherein the protrusion portion is arranged as an oval ring.
